(19) United States
(12) Patent Application Publication
(10) Pub. No.: US 2026/0126730 A1
(43) Pub. Date: May 7, 2026

(54) PROCESS PROXIMITY CORRECTION (PPC) METHOD BASED ON DEEP LEARNING, AND SEMICONDUCTOR MANUFACTURING METHOD COMPRISING THE PPC METHOD

(71) Applicant: SAMSUNG ELECTRONICS CO., LTD, Suwon-si (KR)

(72) Inventors: Sangchul YEO, Suwon-si (KR); Chulho JUNG, Suwon-si (KR); Jaewon YANG, Suwon-si (KR)

(73) Assignee: SAMSUNG ELECTRONICS CO., LTD., Suwon-si (KR)

(21) Appl. No.: 19/197,538

(22) Filed: May 2, 2025

(30) Foreign Application Priority Data
Sep. 26, 2024 (KR) 10-2024-0131073

(51) Int. Cl. G03F 7/00; G03F 1/36

(52) U.S. Cl. CPC G03F 7/70441; G03F 1/36; G03F 7/0005; G03F 7/70504

(57) ABSTRACT

A deep learning-based Process Proximity Correction (PPC) method is provided. The method includes: receiving a first layout of After Clean Inspection (ACI) including a plurality of patterns; extracting a plurality of features of unique patterns from the first layout and sampling the plurality of features of unique patterns; executing an algorithm that optimizes a number of unique patterns sampled in the sampling; identifying optimization conditions and dedose conditions derived from the algorithm; creating a deep learning model based on the optimization conditions and the dedose conditions; and performing correction based on the deep learning model.

### CROSS-REFERENCE TO RELATED APPLICATION

This application claims priority to Korean Patent Application No. 10-2024-0131073, filed on Sep. 26, 2024, in the Korean Intellectual Property Office, the disclosure of which is incorporated by reference herein in its entirety.

### BACKGROUND

The present disclosure relates to a method of manufacturing a semiconductor device, and more particularly, to a process proximity correction (PPC) method and a method of manufacturing a semiconductor device that includes the PPC method.

In semiconductor processes, a photolithography process using a mask may be performed to form patterns on a semiconductor substrate such as a wafer. A mask may be defined as a pattern transfer body in which a pattern shape including an opaque material is formed on a transparent base layer material. In mask manufacturing processes, a required circuit and a layout of the circuit are designed. Design data obtained through Optical Proximity Correction (OPC) may be transmitted as Mask Tape-Out (MTO) design data. Mask Data Preparation (MDP) may be performed based on the MTO design data, and an exposure process and other processes may be carried out on a mask substrate.

### SUMMARY

One or more embodiments provide a deep learning-based Process Proximity Correction (PPC) method having improved reliability and increased process margin, and a method of manufacturing a semiconductor device that includes the PPC method.

Technical problems to be solved by the inventive concept are not limited to the above description, and other technical problems may be clearly understood by one of ordinary skill in the art from the descriptions provided hereinafter.

According to an aspect of an embodiment, a deep learning-based PPC method includes: receiving a first layout of After Clean Inspection (ACI) including a plurality of patterns; extracting a plurality of features of unique patterns from the first layout and sampling the plurality of features of unique patterns; executing an algorithm that optimizes a number of unique patterns sampled in the sampling; identifying optimization conditions and dedose conditions derived from the algorithm; creating a deep learning model based on the optimization conditions and the dedose conditions; and performing correction based on the deep learning model.

According to another aspect of an embodiment, a method of manufacturing a semiconductor device, includes: receiving a first layout of ACI that includes a plurality of patterns; generating a second layout of After Development Inspection (ADI) by performing a deep learning-based PPC method on the first layout; and generating a third layout by performing Optical Proximity Correction (OPC) method on the second layout.

According to another aspect of an embodiment, a method of manufacturing a mask, includes: receiving a first layout including patterns; generating a second layout by performing a deep learning-based PPC method on the first layout; generating a third layout by performing OPC on the second layout; transmitting mask tape-out (MTO) design data indicating the third layout; preparing mask data based on the MTO design data; and exposing a mask substrate to light based on the mask data.

### BRIEF DESCRIPTION OF DRAWINGS

The above and other aspects and features will be more apparent from the following description of embodiments, taken in conjunction with the accompanying drawings, in which:

FIG. 1 is a flowchart schematically showing operations of a method of manufacturing a semiconductor device, according to an embodiment;

FIG. 2 is a detailed flowchart of a deep learning-based Process Proximity Correction (PPC) method included in a method of manufacturing a semiconductor device, according to an embodiment;

FIG. 3 is a detailed flowchart of a sample number optimization algorithm included in a method of manufacturing a semiconductor device, according to an embodiment;

FIG. 4 is a detailed flowchart of an active sampling algorithm that considers multi-weights, which is included in a method of manufacturing a semiconductor device according to an embodiment;

FIG. 5 is a schematic conceptual view of an operation of analyzing feature effectiveness based on an ensemble model, which is included in a method of manufacturing a semiconductor device according to an embodiment;

FIG. 6 is a schematic conceptual view of an operation of calculating Principal Component Analysis (PCA) and extracting principal components, which is included in a method of manufacturing a semiconductor device according to an embodiment;

FIG. 7 is a schematic conceptual view of an operation of calculating Locally Linear Embedding (LLE) and extracting LLE features, which is included in a method of manufacturing a semiconductor device according to an embodiment;

FIG. 8 is a schematic conceptual view of operations of calculating LLE, arranging LLE features in descending order, and sorting the LLE features, which are included in a method of manufacturing a semiconductor device according to an embodiment;

FIG. 9 is a schematic conceptual view of operations of dividing an n-dimensional uniform space based on PCA features and performing binning, which are included in a method of manufacturing a semiconductor device according to an embodiment;

FIG. 10 is a schematic conceptual view of an operation of conducting sampling based on the sorted LLE features from the samples located in the binned uniform space, which is included in a method of manufacturing a semiconductor device according to an embodiment;

FIG. 11 is a graph showing distribution values of errors for each model;

FIG. 12 is a schematic flowchart of operations of a method of manufacturing a mask, according to an embodiment; and

FIG. 13 is a schematic conceptual view of a semiconductor manufacturing device for performing a method of manufacturing a semiconductor, according to an embodiment.

### DETAILED DESCRIPTION

Hereinafter, embodiments are described in detail with reference to the accompanying drawings. It will be understood that, even if a certain step or operation of manufacturing an apparatus or structure is described later than another step or operation, the step or operation may be performed later than the other step or operation unless the other step or operation is described as being performed after the step or operation. The same reference numerals are given to the same elements in the drawings, and repeated descriptions thereof are omitted.

The use of any and all examples, or exemplary language provided herein, is intended merely to better illuminate the invention and does not pose a limitation on the scope of the invention unless otherwise claimed. Embodiments described herein are example embodiments, and thus, the present disclosure is not limited thereto, and may be realized in various other forms. Each embodiment provided in the following description is not excluded from being associated with one or more features of another example or another example embodiment also provided herein or not provided herein but consistent with the present disclosure.

Unless otherwise specifically described, in the present specification, the vertical direction may be defined as the Z direction, and the first horizontal direction and the second horizontal direction may be respectively defined as horizontal directions perpendicular to the Z direction. The first horizontal direction may be referred to as an X direction, while the second horizontal direction may be referred to as a Y direction. The vertical level may refer to a height level in the vertical direction (the Z direction). The horizontal width of the first horizontal direction may refer to the length in the horizontal direction (the X direction and/or the Y direction), and the vertical length may refer to the length in the vertical direction (the Z direction).

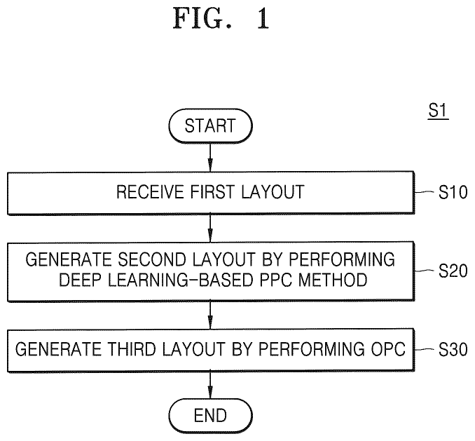

FIG. 1 is a flowchart schematically showing operations of a method of manufacturing a semiconductor device, according to an embodiment.

Referring to FIG. 1, a method S1 of manufacturing a semiconductor device according to an embodiment includes operation S10 of receiving a first layout including a plurality of patterns for manufacturing the semiconductor device. Here, the first layout may be a layout of After Cleaning Inspection (ACI). In this regard, the first layout may be a target layout to be obtained during ACI. ACI may substantially refer to a test conducted after an etching process for forming patterns on a substrate.

Operation S10 of receiving the first layout may correspond to a process of connecting measurement ACI data to the first layout. For example, the measurement ACI data may be converted into data such as polygons, coordinates, or vertices of the first layout, and the sum of left-right or up-down biases at each edge and the size of the polygon (a retarget critical dimension (CD)) may be connected to, or associated with, the measurement ACI data.

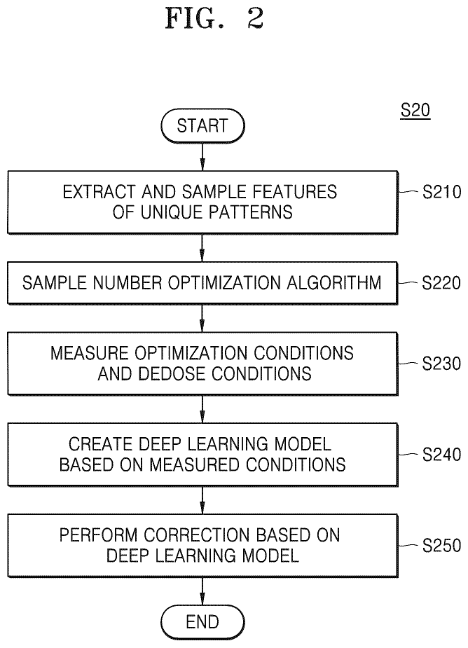

In operation S20, a second layout is generated by performing a deep learning-based Process Proximity Correction (PPC) method on the first layout. Operation S10 may be separate from operation S20, or may be included in operation S20. The method S1 of manufacturing a semiconductor device includes the deep learning-based PPC method (S20 of FIG. 2). PPC may be frequently used to predict ACI CD and correct layouts mainly during the etching process performed after the photolithography process. In this regard, PPC may refer to a process of compensating for the shape change of semiconductor patterns due to the influence of features of the patterns and etch skew during the etching process. For example, PPC may refer to a process of compensating for a shape modification during etching in advance by changing in advance the shape of a portion of a specific pattern, which is expected to be changed through etching, and reflecting the change in the layout.

According to the method S1 of manufacturing a semiconductor device according to an embodiment, PPC may be conducted by performing deep learning-based inference on the features of the patterns in the first layout. The second layout generated through the deep learning-based PPC may be a layout of After Development Inspection (ADI). In this regard, the second layout may be a target layout of the photoresist (PR) to be obtained during ADI. ADI refers to a test conducted after the photolithography process for forming PR patterns on the substrate, and the photolithography process may include an exposure process and a development process. The deep learning-based PPC is explained in more detail below with respect to FIGS. 2 to 10.

Subsequently, in operation S30, Optical Proximity Correction (OPC) is performed on the second layout to generate a third layout. The third layout may be a target layout for a plurality of patterns on the mask.

For reference, to form target patterns on a substrate such as a wafer, the patterns on the mask and the layout for the patterns should be generated first. That is, the target patterns on the substrate may be formed as the patterns on the mask are transferred onto the wafer substrate through the exposure process. Because of the characteristics of the exposure process, the target pattern on the substrate may be different from the pattern on the mask. In addition, because the patterns on the mask are reduced and projected and then transferred to the substrate, the patterns on the mask may have greater sizes than the target patterns on the substrate.

As the patterns become finer, an Optical Proximity Effect (OPE) may occur during the exposure process due to influence or interference of adjacent patterns, and to mitigate the OPE, OPC for restricting the occurrence of the OPE may be carried out to correct the layout for the patterns on the mask.

OPC may include rule-based OPC, and simulation-based or model-based OPC. OPC may include a method of not only modifying the layout of the patterns but adding sub-lithographic features, known as serifs, to the corners of the patterns, or a method of adding Sub-Resolution Assist Features (SRAFs) such as scattering bars.

First, basic data for OPC is prepared. Here, the basic data may include data regarding the shapes of patterns of samples, locations of the patterns, types of measurements for spaces or lines of the patterns, basic measurement values, and the like. Additionally, the basic data may include information such as the thickness, refractive index, and dielectric constant of PR, and may also include a source map regarding an illumination system. The basic data is not limited to the data examples stated above.

After the basic data is prepared, an optical OPC model is generated. The generation of the optical OPC model may include optimization of locations, such as a Defocus Stand (DS) location or a Best Focus (BF) location in the exposure process. In addition, the generation of the optical OPC model may include the generation of optical images considering the diffraction of light or the optical state of exposure equipment itself. The generation of the optical OPC model is not limited to the descriptions above. For example, the generation of the optical OPC model includes various aspects related to optical phenomena occurring during the exposure process.

After the optical OPC model is generated, an OPC model regarding PR is generated. The generation of the OPC model regarding PR may include optimization of a PR threshold value. Here, the PR threshold value may refer to a threshold value at which a chemical change occurs during the exposure process, and for example, the threshold value may be provided as an intensity of exposure light. The generation of the OPC model regarding the PR may include selecting an appropriate model form from among various PR model forms.

The optical OPC model and the OPC model regarding PR are collectively referred to as the OPC model. After the OPC model is generated, an OPC-applied layout is generated by performing a simulation using the OPC model. The third layout stated above may correspond to the OPC-applied layout.

Then, ORC is performed on the OPC-applied layout to determine a final OPC-applied layout. Here, ORC may include Root Mean Square (RMS) calculation on CD errors, Edge Placement Error (EPE) calculation, a pinch error test, a bridge error test, and the like. The items tested during ORC are not limited to those stated above.

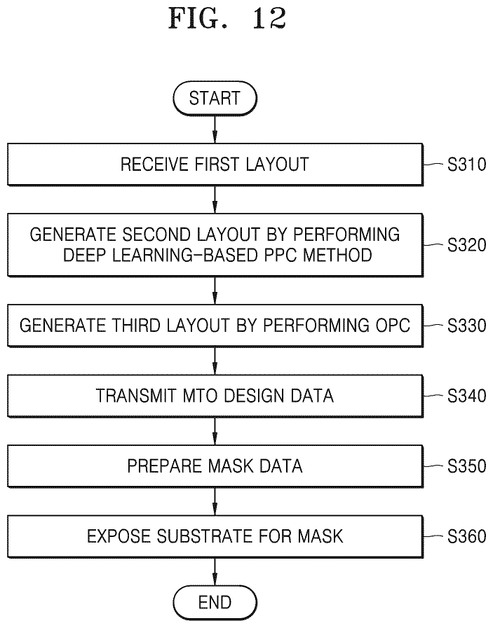

A mask is manufactured by transmitting the final OPC-applied layout Mask Tape-Out (MTO) design data to a manufacturing device (which may be operated by a mask manufacturing team), and patterns may be formed on the wafer by performing the photolithography process, etching process, and the like using the mask, thereby manufacturing a semiconductor device. In the method of manufacturing a semiconductor device according to an embodiment, the semiconductor device may refer to a mask or a semiconductor device on a wafer manufactured using the mask. The method of manufacturing a mask is described in more detail below with respect to FIG. 12.

The method of manufacturing a semiconductor device according to an embodiment may include the deep learning-based PPC method. In addition, the deep learning-based PPC method may include generating an ACI target with an increased process margin, and generating a layout, for example, a layout of ADI, using the generated ACI target. Therefore, according to the method of manufacturing a semiconductor device according to an embodiment, the layout of ADI with high coherence and increased process margin may be generated through the deep learning-based PPC method. Here, the process margin is the same concept as a process window (PW), and the process margin and the PW may be collectively used as the process margin hereinafter.

The method of manufacturing a semiconductor device according to an embodiment may include performing PPC and OPC involving executing an active sampling algorithm by considering a plurality of multi-weights instead of a fixed single condition, which may allow for maximizing the process margin in the semiconductor processes.

FIG. 2 is a detailed flowchart of a deep learning-based PPC method included in a method of manufacturing a semiconductor device, according to an embodiment.

FIG. 2 is described with reference to FIG. 1.

Operation S20 may include operation S210 of extracting a plurality of features of a unique pattern and sampling the extracted features. The unique pattern may include a plurality of unique patterns. The unique pattern may include a circuit pattern with a special shape that is formed on a semiconductor wafer during the processes. For example, the special shape may be an irregular shape that is unique to the device. The plurality of features stated in operation S210 may be features that are distinct from a PCA feature and an LLE feature described below. The PCA feature and the LLE feature may be one of the features stated in operation S210. Therefore, the features extracted in operation S210 and the sampled features may include the PCA feature and the LLE feature described below. For example, one or more features may be extracted from each pattern in a first layout image. In addition, the same type of features or different types of features may be extracted for each pattern. The features may include individual characteristics of the patterns and the effects that each pattern receives from adjacent patterns during etching. Here, the feature of each pattern may refer to, for example, the size and shape of each pattern.

Specifically, the features of the patterns may be summarized into the following items. For example, the features of each pattern may be quantified and extracted as, for example, tone, direction, length, density, sub-layer, width and space of neighboring segments in a normal direction, information on next/previous segments, and harmonics.

Operation S210 of extracting the features of the pattern from the first layout may include tagging the features, which are extracted from each pattern, on each pattern. That is, the effects on each pattern during the etching process may be turned into information and applied to each pattern.

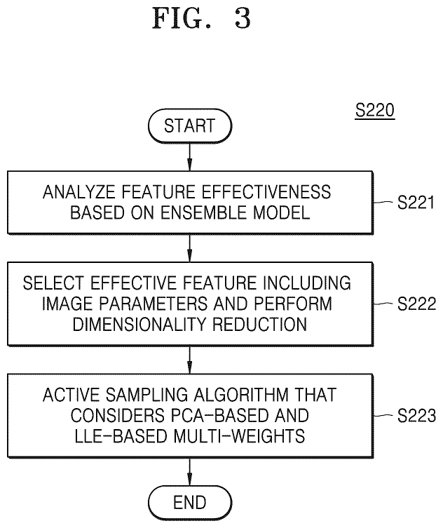

Operation S20 may include operation S220 of executing an algorithm that optimizes the number of samples that are sampled in operation S210. The description that the number of samples is optimized in operation S220 may indicate that the number of samples is minimized by reducing dimensions of the samples. The algorithm in operation S220 is explained in detail with respect to FIG. 3.

In operation S20, both best conditions and dedose conditions are simultaneously and additionally measured for the samples minimized and optimized in operation S220, thus making training data of the model more efficient.

The term “dose” is related to the term “dedose.” The term “dose” may refer to the light exposure amount in the exposure process. That is, the term “dose” may refer to the energy amount of light reaching the surface of PR. During the exposure process, the PR may be exposed to a specific pattern by using light. A unique pattern may be formed by the exposed pattern. Conversely, the term “dedose” refers to reduction in the exposure amount of light. That is, it refers to a process in which light energy reaching the PR is reduced. Dedose may correspond to the presence of defocus and doses that are out of the allowable range from the optimal dose.

Operation S20 may include operation S240 of creating a deep learning model based on the conditions measured in operation S230. In this case, the deep learning model may process the size term of the first layout as a one-to-one function for compensation. In addition, to improve the performance of the prediction model, linear regression that is a one-to-one function and strong in extrapolation may be used, and an advanced deep learning technique with excellent interpolation performance, such as random forest, may be used. Accordingly, correction convergence and the performance of the prediction model may be mutually complemented. Deep learning may be a type of machine learning.

For reference, the amount of information included in the features may be greater than the amount of information used for the rule-based PPC. Therefore, deep learning-based inference on the features, that is, the feature-based PPC, may be more accurate than the rule-based PPC. However, the amount of information included in the features may be less than the amount of information used for model-based PPC. Because of the decrease in the amount of information, the operation amount of the feature-based PPC may be less than the operation amount of the model-based PPC. In addition, because pieces of information, which are similar to noise, are removed and pieces of information, which directly affect individual patterns during etching, are reflected in the inference, the feature-based PPC may be more accurate than the model-based PPC.

After the prediction model is generated, an ACI target with a maximum process margin is generated based on an upper value and a lower value of ACI for each condition. As described above, the condition may be a region in a wafer where the pattern is located. In addition, the condition may include a region in a wafer where the pattern is located.

Operation S20 may include operation S250 of performing correction based on the deep learning model created in operation S240. In operation S250, after the ACI target is generated, the first layout corresponding to the ACI target may be corrected, and the layout of ADI may be generated based on the corrected first layout.

For example, the layout of ADI may be generated by adjusting the intrinsic portions of the patterns, such as the size and shape of the patterns, based on the ACI target and the first layout corresponding thereto. The process of generating the layout of ADI may correspond to the retarget process, and the layout of ADI may be used as an input to OPC later, as described above with reference to FIG. 1. Then, ACI is predicted using the layout of ADI and the prediction model. In this regard, the layout of ACI may be output by inputting the layout of ADI to the prediction model.

FIG. 3 is a detailed flowchart of a sample number optimization algorithm included in a method of manufacturing a semiconductor device, according to an embodiment.

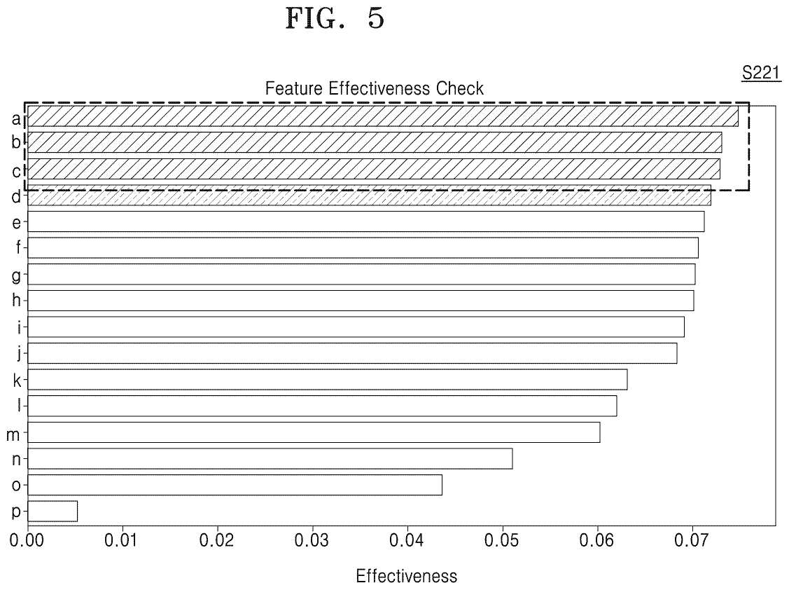

FIG. 3 is described with reference to FIGS. 1 and 2. Operation S220 of executing the algorithm that optimizes the number of samples may include operation S221 of analyzing the effectiveness of features, based on an ensemble model. The effectiveness of the features may be expressed in numbers and arranged in descending order, which is described in more detail with reference to FIG. 5.

Operation S220 of executing the algorithm that optimizes the number of samples may include operation S222 of selecting an effective feature including an image parameter among the effectiveness of the features analyzed in operation S221 and performing dimensionality reduction. The image parameters in operation S222 may include at least one of an Image Log Slope (ILS), a Normalized Image Log Slope (NILS), and a Mask Error Enhancement Factor (MEEF).

The ILS is a parameter used to measure the resolution and definition of patterns formed on the PR. That is, the ILS is an indicator showing how the light intensity changes during the exposure process. The ILS may be used to measure how much the light intensity, i.e., dose, changes at the boundary of the unique pattern and may affect edge definition on an exposed image.

The ILS is defined as a differential value obtained by differentiating the log value of the light intensity relative to location and may be represented by <Equation 1> below.

$$ILS = \frac{d ( log I )}{dx} \qquad Equation 1$$

In Equation 1, I represents the intensity of light.

That is, the greater the ILS value is, the more the light intensity changes at the pattern boundary. Drastic changes in the light intensity result in clearer and more accurate unique patterns. On the contrary, when the ILS value is small, the boundary becomes relatively blurred, and the accuracy of the patterns may decrease. Therefore, the ILS may be proportional to the resolution of the pattern edge.

The NILS is a value obtained by normalizing the ILS with the contrast that is the contrast ratio of an image. When the ILS indicates the rate of change in light at the pattern boundary, the NILS may be used for resolution performance evaluation by normalizing the ILS based on the thickness of the PR or exposure conditions.

The NILS is defined as a value obtained by dividing the ILS by the contrast ratio of the pattern and may be represented by <Equation 2> below.

$$NILS = \frac{NILS}{{I}_{max} - {I}_{min}} \qquad Equation 2$$

In <Equation 2>, Iₘₐₓ represents the highest light intensity in an image, while Imin represents the lowest light intensity in the image.

The NILS may be proportional to the resolution.

The MEEF is an indicator used to evaluate the effect of an error in a mask pattern on a pattern on a wafer. When the mask pattern is imperfect, the MEEF is an indicator showing how much the error is amplified in the pattern on the wafer.

The MEEF refers to the effect of the change in the mask pattern on the wafer pattern and may be defined as shown in <Equation 3> below.

$$MEEF = \frac{ΔWafer Critical Dimension ( CD )}{Δ Mask CD} \qquad Equation 3$$

Here, ΔWafer CD represents a pattern change on a wafer, and ΔMask CD represents a pattern change on a mask.

As shown in <Equation 3>, when the MEEF value is 1, it may indicate that the pattern change on the mask is directly reflected onto the wafer pattern. When the MEEF value is greater than 1, a small pattern change on the mask may appear greater on the wafer. When the MEEF value is less than 1, the change on the mask may have less impact the wafer pattern. When the MEEF is high, a small error in the mask is greatly amplified on the wafer, and thus the error may be highly sensitive to variations in the process, especially in fine circuit patterns.

The ILS, NILS, and MEEF included in the image parameters are only examples, and the image parameters may include additional parameters besides those listed above. The dimension reduced in operation S222 may be two dimensions, three dimensions, or even higher dimensions. The dimensionality of the reduced dimensions may correspond to the number of effective features selected.

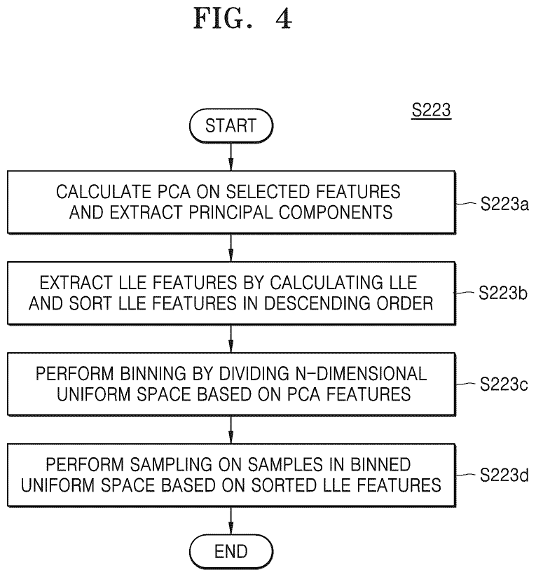

Operation S220 of executing the algorithm that optimizes the number of samples may include operation S223 of arranging the samples based on the reduced dimension in operation S222 and executing an active sampling algorithm that considers multi-weights for the samples. The multi-weight may include Principal Component Analysis (PCA) and Locally Linear Embedding (LLE) that is a type of non-linear dimension reduction method. Operation S223 is described in more detail with reference to FIG. 4. The PCA features and the LLE features may differ from the features analyzed and set in operation S221 and operation S222 and/or the effective features. The features analyzed and set in operation S221 and operation S222 and/or the effective features may include the PCA features and the LLE features.

FIG. 4 is a detailed flowchart of an active sampling algorithm that considers multi-weights, which is included in a method of manufacturing a semiconductor device according to an embodiment.

FIG. 4 is described with reference to FIGS. 1 to 3. Referring to FIG. 4, operation S223 may include operation S223a of calculating PCA for the effective features selected in operation S222 and extracting a principal component.

When the effectiveness of each feature is analyzed and the effective feature is selected, the number of selected effective features may be n (where n is a positive integer). In operation S223a, PCA may be performed for n features, and a principal component may be extracted to reduce dimensionality.

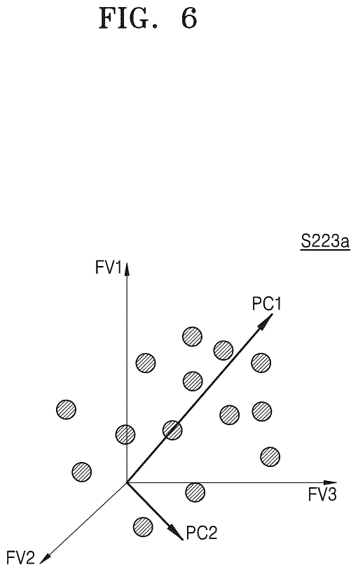

PCA according to an embodiment may be a dimensionality reduction technique used in a deep learning model. PCA may be used to convert high-dimensional data into low-dimensional data and reduce the amount of operations required for learning or extract important features of data. Here, the important features of the data may correspond to the principal component extracted in operation S223a as an example. More specifically, PCA may be a method of projecting high-dimensional data onto a low-dimensional space. During PCA, a direction in which data distribution is maximized may be identified. When image data is used, pixel values may be expressed as high-dimensional vectors, and PCA may be used to convert the high-dimensional vectors into a low-dimensional space and remove unnecessary information while preserving key features. The PCA process is described in more detail with reference to FIG. 6.

In operation S223, LLE features may be extracted by calculating LLE for the principal components obtained through PCA in operation S223a, and the LLE features may be arranged in descending order.

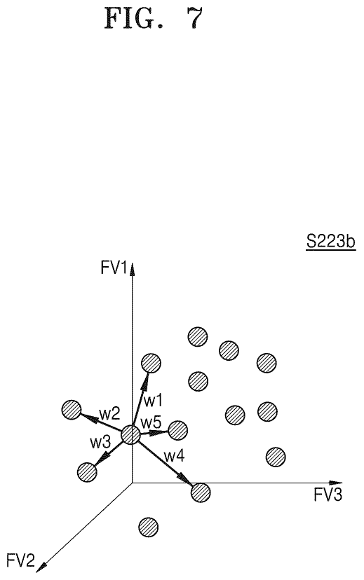

LLE may refer to a non-linear dimensionality reduction technique. In an embodiment, LLE may preserve the structure of data by mapping the data into a low-dimensional space while maintaining local linear relationships of the data. The process of extracting the LLE features, including the nearest neighbor sample search and the like, is described in detail with reference to FIG. 7.

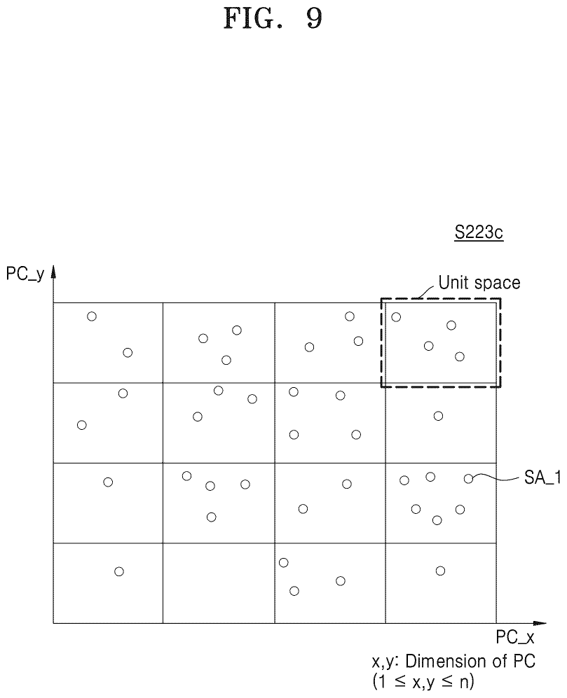

Operation S223 may include operation S223c of binning, that is a process in which variables are grouped into discrete intervals by partitioning data into a uniform n-dimensional space, based on the PCA features extracted in operation S223a. The n-dimension forming the uniform space may correspond to the number of PCA features. Binning may define regions corresponding to specific intervals to classify samples. The regions may be referred to as unit spaces and are described in more detail with reference to FIG. 9.

Operation S223 may include operation S223d of performing sampling based on the LLE features that are sorted in descending order from among the samples arranged in the binned uniform space in operation S223c.

FIG. 5 is a schematic conceptual view of an operation of analyzing feature effectiveness based on an ensemble model, which is included in a method of manufacturing a semiconductor device according to an embodiment.

Referring to FIG. 5 together with FIG. 3, the feature effectiveness of unique patterns may be analyzed based on an ensemble model. The feature effectiveness may be analyzed in plural, as shown in FIG. 5. While checking the feature effectiveness in FIG. 5, the features are represented by letters a to p, but specific names of the features may vary in each process. The features a to p may be arranged in descending order. For example, among the features represented by the letters a to p, the feature represented by the letter a may have the greatest effectiveness, and the feature represented by the letter p may have the least effectiveness. The features a to c, which have the greatest effectiveness values among the features a to p arranged in descending order, may be extracted. Among the features analyzed in operation S221, the features a to c may be effective features selected in operation S222. The three features extracted may be used to reduce dimensionality in operation S222. Therefore, the dimensionality of the reduced dimension may be three dimensions corresponding to the number of selected effective features.

FIG. 6 is a schematic conceptual view of an operation of calculating PCA and extracting principal components, which is included in a method of manufacturing a semiconductor device according to an embodiment.

FIG. 6 is described with reference to FIGS. 4 and 5. Referring to FIG. 6, the number of extracted effective features shown in FIG. 5 is three (i.e., the three features which have the greatest effectiveness values), and thus, three dimensions may be formed. Each axis has a feature value ranging from 1 to 3. The samples may be arranged in the dimension reduced to have feature values from 1 to 3. A plurality of principal components, that is, a first principal component PC1 and a second principal component PC2, may be obtained by calculating PCA for the samples that are three-dimensionally arranged.

FIG. 6 shows the first principal component PC1 and the second principal component PC2 calculated in the space having the axes with the feature values of 1 to 3, and the process of calculating the PCA features is described as follows. In an embodiment, PCA may undergo a data normalization process. During the data normalization, the mean of individual features becomes 0, and the variance may become unit variance. Then, covariance matrix calculation may be conducted. The covariance matrix of data may be calculated to identify the correlation between individual features. Eigenvalues and eigenvectors may be calculated. In this regard, the eigenvalues and the eigenvectors in the covariance matrix may be calculated, and the axis for explaining the data distribution may be obtained. The axis with a large eigenvalue may accurately explain the variance of the data. Finally, the eigenvectors may be sorted. The eigenvectors may be arranged based on the eigenvalues, and top eigenvalues may be selected to project the data onto a low-dimensional space. The projected eigenvectors may be PC1 and PC2 of FIG. 6. PC1 may be different from PC2.

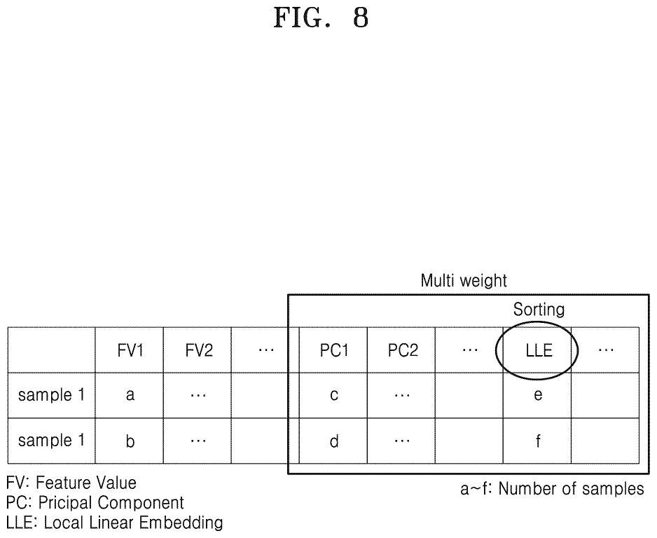

FIG. 7 is a schematic conceptual view of an operation of calculating LLE and extracting LLE features, which is included in a method of manufacturing a semiconductor device according to an embodiment. FIG. 8 is a schematic conceptual view of operations of calculating LLE, arranging LLE features in descending order, and sorting the LLE features, which are included in a method of manufacturing a semiconductor device according to an embodiment.

FIG. 7 is described with reference to FIGS. 4 to 6. Operation S223b may be sequentially performed after operation S223a, but embodiments are not limited thereto and operation S223b may be performed simultaneously with operation S223a. That is, PCA features and LLE features may overlap and be analyzed. Therefore, the multi-weights, that is, PCA and LLE, may be simultaneously considered. In operation S223b, the LLE features may be calculated and extracted for the samples arranged in the above-described space having the axes with the feature values of 1 to 3.

The process of extracting the LLE features may start with a nearest neighbor search process. The nearest neighbor search refers to a process of finding n nearest neighboring points for each data point. Referring to FIG. 7, five nearest neighboring points are found for one of samples arranged in a three-dimensional space. Reference symbols w1 to w5 may be indicators showing distances between neighboring points. After the nearest neighbor search, a process of calculating a local linear relationship may be performed. It is assumed that each data point is represented by a linear combination of neighboring points, and weights of the linear combinations may be calculated. Finally, dimensionality reduction may be performed. In this regard, new low-dimensional coordinates may be found to maintain the same weights in the low-dimensional space.

Referring to FIG. 8, an effective feature may be selected for each sample, and a plurality of principal components may be extracted from the reduced dimension, based on the selected effective features. In addition, LLE features may be calculated in the reduced dimension, based on the selected effective features. The PCA feature may correspond to a principal component, while the LLE feature may correspond to a multi-weight. The LLE features may be sorted in descending order, and the greatest LLE may be an LLE feature sorted within the multi-weight.

FIG. 9 is a schematic conceptual view of operations of dividing an n-dimensional uniform space based on PCA features and performing binning, which are included in a method of manufacturing a semiconductor device according to an embodiment.

Referring to FIG. 9, a uniform space may form a unit space. The term “unit space” may correspond to the uniform space. The uniform space may correspond to a portion of the area formed in a reduced-dimensional space. The reduced dimension shown in FIG. 9 may have the same dimensionality as the number of principal components extracted as described above with reference to FIG. 6. In this regard, the number of principal components extracted as described with reference to FIG. 6 is two, that is, PC1 and PC2; thus, the reduced dimension shown in FIG. 9 may be two-dimensional. The two-dimensional space defined by two axes may be evenly divided into equal areas. The division into equal areas may correspond to binning. Therefore, operation S223c may be performed as shown in FIG. 9. The equal area may correspond to the area of the uniform space. A plurality of uniform spaces may be provided. Samples may be arranged in the uniform spaces. The number of samples arranged in a uniform space may be one or at least two. However, not every uniform space may include samples. In this regard, there may be uniform spaces without samples. The samples arranged in a uniform space may include first samples SA_1.

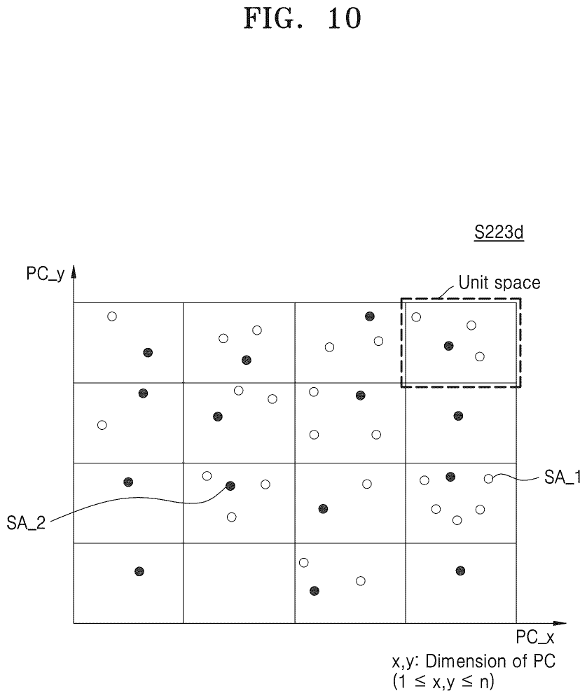

FIG. 10 is a schematic conceptual view of an operation of conducting sampling based on the sorted LLE features from the samples located in the binned uniform space, which is included in a method of manufacturing a semiconductor device according to an embodiment.

FIG. 10 is described with reference to FIGS. 8 and 9. For one of the first samples SA_1 arranged in each of the binned uniform spaces in FIG. 9, a second sample SA_2 may be designated. The second sample SA_2 may be a sample corresponding to the LLE feature sorted as shown in FIG. 8. The second sample SA_2 may designate one of the first samples SA_1. When the first samples SA_1 are placed in a uniform space, the second sample SA_2 may correspond to one of the first samples SA_1. Therefore, when a plurality of first samples SA_1 are arranged in a single uniform space, the second sample SA_2 may correspond to one of the first samples SA_1. In an embodiment, when the first samples SA_1 are not arranged in a single uniform space, the second sample SA_2 may not be arranged in the uniform space. Therefore, the second sample SA_2 may be arranged in the uniform space only when the first samples SA_1 are arranged in the uniform space. The second sample SA_2 cannot be provided in plurality in a single uniform space.

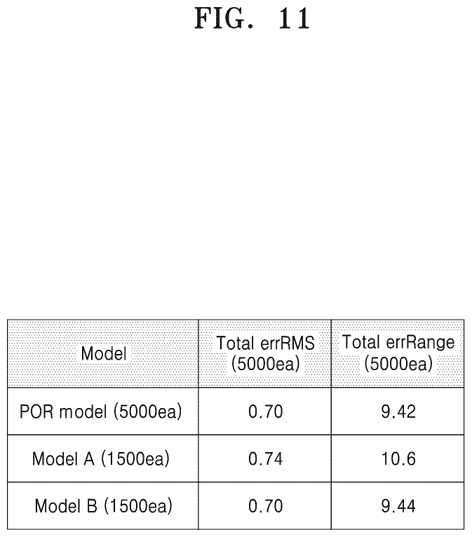

FIG. 11 is a graph showing distribution values of errors for each model.

A Process of Record (POR) model shown in FIG. 11 represents a model based on POR. That is, the POR model refers to process standards in various industries such as semiconductors, electronics, and manufacturing and may correspond to documented criteria outlining methods and procedures for performing specific tasks conducted during product production. The POR model may include standard work procedures and best practices to ensure quality, performance, and safety. In the POR model, tests were conducted on 5,000 samples. The RMS of the total error in the POR model was measured as 0.70, and the range value of the total error was measured as 9.42. The range shown in FIG. 11 may represent the numerical range of errors.

Model A may correspond to a random selection model. In Model A, tests were conducted on 1,500 samples. The RMS of the total error in Model A was measured as 0.74, and the range value of the total error was measured as 10.6. In this regard, in the case of Model A that is a random selection model, it was found that not only the RMS but the range value of the total error were measured to be greater than those of the POR model. Therefore, it was found that Model A is less optimized than the POR model.

Model B may correspond to a deep learning model according to an embodiment. In Model B, tests were conducted on 1,500 samples. The RMS of the total error in Model B was measured as 0.70, and the range value of the total error was measured as 9.44. That is, in the case of Model B that is a deep learning model according to an embodiment, it was identified that both the RMS and the range value of the total error were measured similarly to those of the POR model. Therefore, it was found that Model B is optimized similarly to the POR model even though fewer samples are used compared to the POR model. In this regard, it was identified that the coherence and stability of the POR model are maintained despite a relatively small number of samples.

FIG. 12 is a schematic flowchart of operations of a method of manufacturing a mask, according to an embodiment. The descriptions already provided with reference to FIGS. 1 to 11 are briefly repeated or omitted.

Referring to FIG. 12, operation S310 of receiving a first layout, operation S320 of generating a second layout, and operation S330 of generating a third layout are sequentially performed. Operation S310 of receiving the first layout and operation S330 of generating the third layout may be substantially the same as operation S10 of receiving the first layout and operation S30 of generating the third layout, wherein operation S10 and operation S30 are shown in FIG. 1. Therefore, the detailed descriptions of operations S310 to S330 are omitted. The third layout may correspond to an OPC-applied layout and may also represent a final OPC-applied layout that has passed ORC.

In operation S340, the image of the final OPC-applied layout is transmitted to a manufacturing device (which may be operated by a mask manufacturing team) as MTO design data. MTO may indicate that final mask data obtained through OPC is delivered to the mask manufacturing team for mask production. Therefore, the MTO design data may be substantially the same as data regarding the image of the final OPC-applied layout that is obtained through OPC. Such MTO design data may have a graphic data format used in Electronic Design Automation (EDA) software, etc. For example, the MTO design data may have a data format such as Graphic Data System II (GDS2) or Open Artwork System Interchange Standard (OASIS).

In operation S350, Mask Data Preparation (MDP) is performed. The MDP may include, for example, i) format conversion called fracturing, ii) augmentation of barcodes for mechanical readout, standard mask patterns for inspection, job decks, and the like, and iii) automatic and manual verification. Here, the job deck may refer to generation of a text file regarding a series of instructions, such as arrangement information of multi-mask files, a reference dose, and an exposure rate or mode.

The format conversion, that is, fracturing, may refer to a process of segmenting the MTO design data into respective regions and converting the MTO design data into a format for electron beam exposure equipment. The fracturing may include data manipulation, for example, scaling, data sizing, data rotation, pattern reflection, color inversion, and the like. During the conversion process through the fracturing, corrections may be made to numerous systematic errors that may occur at any stage during the transfer of design data to an image on a wafer. The data correction process for the systematic errors is referred to as Mask Process Correction (MPC) and may involve, for example, line width adjustment called Critical Dimension (CD) adjustment and a process of improving pattern placement accuracy. Therefore, the fracturing may help improve the quality of the final mask and may be a process performed prior to correcting the mask process. Here, the systematic errors may be caused by distortions occurring during an exposure process, a mask development and etching process, and a wafer imaging process.

The MDP may include MPC. As described above, the MPC refers to a process of correcting errors occurring during an exposure process, that is, systematic errors. Here, the exposure process may include electron beam writing, development, etching, baking, and the like. In addition, data processing may be performed before the exposure process. The data processing may be a sort of pre-processing process for the mask data and include grammar checking for the mask data, predicting exposure time, and the like.

A mask substrate is exposed to light based on the mask data in operation S360. Here, exposure may refer to, for example, electron beam writing. Here, the electron beam writing may be conducted, for example, using a multi-beam mask writer (MBMW) in a gray writing manner. In addition, the electron beam writing may be performed using a variable shape beam (VSB) exposure device.

After the MDP, a process of converting the mask data into pixel data may be performed before the exposure process. Pixel data may be data that is directly used for actual exposure and may include data regarding a shape to be exposed and data regarding a dose assigned to each shape. Here, the data regarding a shape to be exposed may be bitmap data that is obtained as shape data, which is vector data, is converted through rasterization.

After the exposure process, the mask may be completed through a series of processes. The series of processes may include, for example, development, etching, cleaning, and the like. The series of processes for mask production may also include measurement, defect inspection, or defect repair. A pellicle coating process may be included. Here, the pellicle coating process may refer to a process in which, once it is confirmed during the final cleaning and inspection that no pollutant particles or chemical stains are present, a pellicle is attached to the mask surface to protect the mask from contamination during the shipment and lifespan of the mask.

The method of manufacturing a mask according to an embodiment may employ the deep learning-based PPC method, and an ML-based PPC method may be performed by generating an ACI target with a maximized process margin and using the ACI target. Therefore, according to the method of manufacturing a mask according to an embodiment, a mask layout with high alignment accuracy and maximized process margin may be produced through PPC and OPC. Consequently, according to the method of manufacturing a mask according to an embodiment, a reliable mask may be manufactured using the mask layout with an increased process margin and a semiconductor device with improved reliability may be manufactured using the mask.

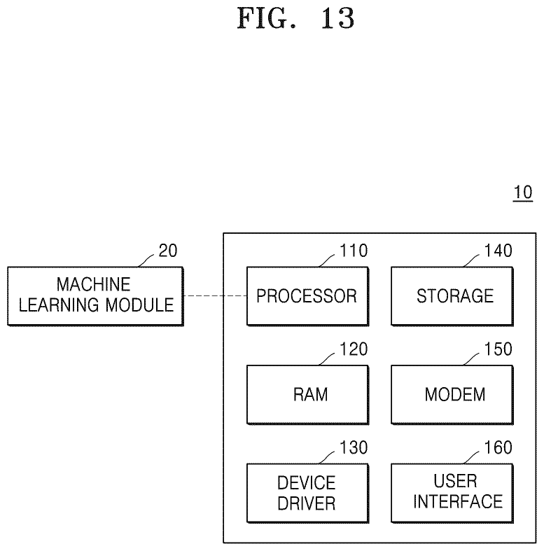

FIG. 13 is a schematic conceptual view of a semiconductor manufacturing device for performing a method of manufacturing a semiconductor, according to an embodiment.

FIG. 13 is described with reference to FIGS. 1 to 12. Referring to FIG. 13, a computing device 10 according to one or more embodiments may include a plurality of processors 110, Random Access Memory (RAM) 120, a device driver 130, a storage 140 providing a storage space, a modem 150, and a plurality of user interfaces 160.

At least one of the processors 110 may execute a semiconductor process machine learning module 20. The semiconductor process machine learning module 20 may execute a machine learning model corresponding to the deep learning model of embodiments. The semiconductor process machine learning module 20 may produce a layout for manufacturing a semiconductor device, based on machine learning. For example, the semiconductor process machine learning module 20 may execute commands (or code) executed by at least one of the processors 110. In this case, at least one processor may load the commands (or code) of the semiconductor process machine learning module 20 into the RAM 120.

In an embodiment, at least one processor may be designed to implement the semiconductor process machine learning module 20. As another example, at least one processor may be manufactured to implement various machine learning modules. At least one processor may implement the semiconductor process machine learning module 20 by receiving information corresponding to the semiconductor process machine learning module 20.

Using the semiconductor process machine learning module 20 executed by at least one of the processors 110 according to an embodiment, a layout may be generated based on PPC.

During the PPC according to one or more embodiments, information regarding an After Cleaning Image (ACI) state of a target layout, which is subject to the PPC, may be predicted. In more detail, through the PPC according to one or more embodiments, CD of multiple patterns, that is, pattern line widths, may be predicted based on the ACI state of the target layout.

The processors 110 may include, for example, at least one processor such as a Central Processing Unit (CPU) or an Application Processor (AP). The processors 110 may also include at least one special-purpose processor such as a neural processing unit, a neuromorphic processor, or a Graphics Processing Unit (GPU). The processors 110 may include two or more processors of the same type.

The RAM 120 may be used as an operation memory of the processors 110 or as a main memory or system memory of the computing device 10. The RAM 120 may include volatile memory such as Dynamic Random Access Memory (DRAM) or Static RAM (SRAM) or non-volatile memory such as Phase Change RAM (PRAM), Ferroelectric RAM (FRAM), Magnetic RAM (MRAM), or Resistive RAM (RRAM).

The device driver 130 may control peripheral devices such as the storage 140, the modem 150, and the user interfaces 160, according to the requests from the processors 110. The storage 140 may include a fixed storage device such as a hard disk drive or a solid-state drive or a removable storage device such as an external hard disk drive, an external solid-state drive, or a removable memory card.

The modem 150 may provide remote communication with an external device. The modem 150 may provide wireless or wired communication with an external device. The modem 150 may communicate with an external device through at least one of various communication forms such as Ethernet, Wi-Fi, LTE, and 5G mobile communication.

The user interfaces 160 may receive information from a user and provide information to the user. The user interfaces 160 may include at least one user output interface such as a display or a speaker and at least one user input interface such as a mouse, a keyboard, or a touch input device.

The commands (or code) of the semiconductor process machine learning module 20 may be received by the modem 150 and stored in the storage 140. The commands (or code) of the semiconductor process machine learning module 20 may be stored in a removable storage device and connected to the computing device 10. The commands (or code) of the semiconductor process machine learning module 20 may be loaded into the RAM 120 from the storage 140 and then executed.

At least one of the processors 110 according to an embodiment may generate layouts. More specifically, at least one of the processors 110 according to one or more embodiments may execute the semiconductor process machine learning module 20. Then, the semiconductor process machine learning module 20 according to one or more embodiments may generate layouts for manufacturing a semiconductor device based on machine learning. In more detail, the semiconductor process machine learning module 20 according to one or more embodiments may perform PPC on the layouts for manufacturing a semiconductor device.

Using the semiconductor process machine learning module 20 executed by at least one of the processors 110 according to one or more embodiments, a layout may be generated through PPC. In this case, the processors 110 according to one or more embodiments may convert the layout into an image and perform PPC thereon through deep learning.

At least one of the processors 110 according to one or more embodiments may convert a layout, which is subject to PPC, into an image to perform PPC.

A target layout, which is used for PPC by at one of the processors 110 according to one or more embodiments, may include vector data. In this case, when the target layout is converted into an image, vectors in the target layout may be converted into pixels, thereby generating an image.

While aspects of embodiments have been particularly shown and described, it will be understood that various changes in form and details may be made therein without departing from the spirit and scope of the following claims.

What is claimed is:

1. A deep learning-based Process Proximity Correction (PPC) method comprising:
receiving a first layout of After Clean Inspection (ACI) comprising a plurality of patterns;
extracting a plurality of features of unique patterns from the first layout and sampling the plurality of features of unique patterns;
executing an algorithm that optimizes a number of unique patterns sampled in the sampling;
identifying optimization conditions and dedose conditions derived from the algorithm;
creating a deep learning model based on the optimization conditions and the dedose conditions; and
performing correction based on the deep learning model.

2. The deep learning-based PPC method of claim 1, wherein the executing of the algorithm comprises analyzing effectiveness of the plurality of features of unique patterns, based on an ensemble model.

3. The deep learning-based PPC method of claim 2, wherein the executing of the algorithm comprises:
selecting an effective feature comprising a plurality of image parameters; and
performing dimensionality reduction.

4. The deep learning-based PPC method of claim 3, wherein the is executed based on at least one multi-weight.

5. The deep learning-based PPC method of claim 4, wherein the at least one multi-weight is based on Principal Component Analysis (PCA) and Locally Linear Embedding (LLE).

6. The deep learning-based PPC method of claim 4, wherein the executing of the algorithm further comprises:
calculating Principal Component Analysis (PCA) for features, which are selected in the selecting of the effective feature and the performing of the dimensionality reduction; and
extracting principal components.

7. The deep learning-based PPC method of claim 6, wherein the principal components extracted after the calculating of the PCA comprise at least two principal components.

8. The deep learning-based PPC method of claim 6, wherein the executing of the algorithm comprises:
calculating Locally Linear Embedding (LLE) for features, which are selected in the selecting of the effective feature and the performing of the dimensionality reduction;
extracting LLE features; and
sorting the LLE features in descending order.

9. The deep learning-based PPC method of claim 8, wherein the executing of the algorithm comprises performing binning by dividing a uniform space based on the calculated PCA features, and
wherein a number of dimensions in the uniform space corresponds to a number of PCA features.

10. The deep learning-based PPC method of claim 9, wherein the executing of the algorithm comprises performing sampling on samples in the uniform space, based on the extracted LLE features.

11. A method of manufacturing a semiconductor device, the method comprising:
receiving a first layout of After Clean Inspection (ACI) that comprises a plurality of patterns;
generating a second layout of After Development Inspection (ADI) by performing a deep learning-based Process Proximity Correction (PPC) method on the first layout; and
generating a third layout by performing Optical Proximity Correction (OPC) method on the second layout.

12. The method of claim 11, wherein the generating of the second layout comprises:
extracting a plurality of features of unique patterns from the first layout and sampling the plurality of features of unique patterns;
executing a first algorithm that optimizes a number of unique patterns that are sampled;
identifying optimization conditions and dedose conditions derived from the first algorithm;
creating a deep learning model based on the optimization conditions and the dedose conditions that are identified; and
performing correction based on the deep learning model.

13. The method of claim 12, wherein the executing of the first algorithm comprises:
analyzing feature effectiveness of the unique patterns, based on an ensemble model;
selecting an effective feature that comprises a plurality of image parameters;
performing dimensionality reduction; and
executing a second algorithm that considers at least one multi-weight.

14. The method of claim 13, wherein the plurality of image parameters comprise at least one of Image Log Slope (ILS), Normalized Image Log Slope (NILS), and Mask Error Enhancement Factor (MEEF).

15. The method of claim 13, wherein the at least one multi-weight is based on Principal Component Analysis (PCA) and Locally Linear Embedding (LLE).

16. The method of claim 13, wherein the executing of the second algorithm comprises:
for features selected in the selecting of the effective feature comprising the plurality of image parameters and the performing of the dimensionality reduction, extracting principal components by calculating Principal Component Analysis (PCA);
calculating Locally Linear Embedding (LLE);
extracting LLE features; and
sorting the LLE features in descending order, and
wherein at least two principal components are extracted after the calculating of the PCA.

17. The method of claim 16, wherein the executing of the second algorithm comprises:
performing binning by dividing a uniform space based on the calculated PCA features to obtain a binned uniform space; and
performing sampling on samples in the binned uniform space, based on the extracted LLE features.

18. The method of claim 17, wherein, based on samples being in the binned uniform space, one LLE feature-based sample exists for each uniform space.

19. A method of manufacturing a mask, the method comprising:
receiving a first layout comprising patterns;
generating a second layout by performing a deep learning-based Process Proximity Correction (PPC) method on the first layout;
generating a third layout by performing Optical Proximity Correction (OPC) on the second layout;
transmitting mask tape-out (MTO) design data indicating the third layout;
preparing mask data based on the MTO design data; and
exposing a mask substrate to light based on the mask data.

20. The method of claim 19, wherein the generating of the second layout comprises:
extracting a plurality of features of unique patterns from the first layout;
sampling the plurality of features of unique patterns;
executing a first algorithm that optimizes a number of unique patterns that are sampled;
identifying optimization conditions and dedose conditions derived from the first algorithm;
building a deep learning model based on the optimization conditions and the dedose conditions; and
performing correction based on the deep learning model,
wherein the executing of the first algorithm comprises:
analyzing feature effectiveness of the unique patterns, based on an ensemble model;
selecting an effective feature that comprises a plurality of image parameters;
performing dimensionality reduction; and
executing a second algorithm that considers multi-weights, based on PCA and LLE.
